(19) United States
(12) Patent Application Publication
(10) Pub. No.: US 2005/0112822 A1
(43) Pub. Date: May 26, 2005

(54) Method in the fabrication of a monolithically integrated high frequency circuit

(76) Inventor: Andrej Litwin, Danderyd (SE)

Correspondence Address: Andreas Grubert;Baker Botts L.L.P., One Shell Plaza, 910 Louisiana, Houston, TX, 77002-4995, US

(21) Appl. No.: 10/947,801

(22) Filed: Sep. 23, 2004

(30) Foreign Application Priority Data
Nov. 21, 2003 (SE) 0303099-6

(51) Int. Cl. H01L 21/336

(52) U.S. Cl. 438/270; 438/302

(57) ABSTRACT

A method in the fabrication of an integrated high frequency circuit including a DMOS transistor device comprises the steps of providing a substrate, etching a trench in a region defined for an extended drain for the DMOS transistor, and doping a region below the trench and a region at a side of the trench to a first doping type by means of ion implantation in the etched open trench through a mask, wherein the ion implantation is effectuated in a direction, which is inclined at an angle to the normal of the surface of the substrate, to thereby create a partly lateral and partly vertical current path in the extended drain. The method comprises further the steps of filling the trench with an insulating material to form a shallow trench isolation region, and forming a gate, a channel region, a source, and a drain for the DMOS transistor.

### PRIORITY

This application claims priority to Swedish application no. 0303099-6 filed Nov. 21, 2003.

### TECHNICAL FIELD OF THE INVENTION

The present invention generally relates to the field of integrated circuit technology, and more specifically the invention relates to a method in the fabrication of a monolithically integrated circuit, to a DMOS transistor device, and to a monolithically integrated circuit, respectively.

### DESCRIPTION OF RELATED ART AND BACKGROUND OF THE INVENTION

The ever-increasing market for microwave power amplifiers in PCS, CDMA, and WCDMA systems requires low cost, and ease of use technology that can provide high power and good linearity performance. LDMOS devices started to replace bipolar devices in base station applications 3-4 years ago and LDMOS has for multiple reasons become the leading technology for base station power amplifier applications. The LDMOS device has high gain and shows excellent back-off linearity. The breakdown voltage BV_{dss} can be easily adjusted by the layout to fit different application voltages.

The integration of LDMOS transistors into a radio frequency BiCMOS process without affecting other devices is disclosed in O. Bengtsson, A. Litwin, and J. Olsson: “Small-Signal and Power Evaluation of Novel BiCMOS-Compatible Short Channel LDMOS Technology”, IEEE Transactions on Microwave Theory and Techniques, Vo. 51, No. 3, March 2003, and in the published U.S. patent application No. 20020055220 A1. This provides for low cost and more efficient linear integrated radio frequency power amplifiers with multiple amplification steps on the very same chip.

To optimize the high frequency properties of an LDMOS transistor, the drain drift region should have a non-conform distribution of doping concentration along the current path, with highest concentration at the drain contact. An example of an advanced method to achieve this can be found in T. M. L. Lai et al., “Implementation of linear doping profiles for high voltage thin-film SOI devices”, Proceedings of the 7th International Symposium on Power Semiconductor Devices and ICs, ISPSD '95 (EEE Cat. No.95CH35785), 1995, pp. 315-20.

In more conventional high frequency LDMOS transistors the drift region is divided in two segments, where the segment closest to the gate region is implanted with the lowest n-type dopant dose.

### SUMMARY OF THE INVENTION

RF LDMOS transistors incorporated in CMOS or BiCMOS processes require a drain drift region optimized for each particular application. The lightly doped wells used for this purpose and normally present in standard processes will not in a general case fulfill the requirements needed for an optimized drain drift region. This is particularly accentuated in a technology using shallow trench isolation (STI), where the STI occupies a large portion of the well, which makes it almost impossible to use conventional wells. To optimise the well doping concentration and distribution, additional wells need to be implemented, thereby requiring several additional masks and treatments that may affect other transistors on the chip.

Accordingly, it is an object of the present invention to provide a method in the fabrication of an integrated circuit, particularly an integrated circuit for radio frequency applications, including a DMOS transistor device, which DMOS transistor device overcomes the problems associated with the prior art described above.

It is a further object of the invention to provide such a method, which provides for the fabrication of a DMOS transistor device that occupies smaller chip area than that of a prior art DMOS transistor.

Further, it is an object of the invention to provide a DMOS transistor device in an integrated circuit, particularly an integrated circuit for radio frequency applications, which accomplishes the above objects.

Still further, it is an object of the invention to provide an integrated circuit comprising a DMOS transistor device of the above kind.

These objects can according to the present invention be attained by method in the fabrication of a monolithically integrated high frequency circuit including a DMOS transistor device, comprising the steps of:
providing a semiconductor substrate,
defining, for the DMOS transistor device, a region for an extended drain in the substrate,
etching a trench in the region for the extended drain,
doping a region below the trench and a region at a side of the trench to a first doping type by means of ion implantation in the trench through a mask, the ion implantation being effectuated in a direction, which is inclined at an angle to the normal of the surface of the substrate, to thereby create a partly lateral and partly vertical current path in the defined region for the extended drain,
filling the trench with an insulating material to form a shallow trench isolation region, and
forming, for the DMOS transistor device, a gate, source and drain regions doped to the first doping type, and a channel region doped to a second doping type, the channel region interconnecting the source and drain regions via the region for the extended drain.

The ion implantation can be performed to obtain at least two different segments with different doping concentrations in the doped regions below and at the side of the trench. The ion implantation in the trench to form the doped regions below and at the side of the trench can be performed at an angle, which depends on the relation between the desired dopant concentrations of the doped regions below and at the side of the trench. The ion implantation in the trench to form the doped regions below and at the side of the trench can be performed to obtain a higher dopant concentration in the region below the trench than in the region at the side of the trench. The ion implantation in the trench to form the doped regions below and at the side of the trench can also be performed to obtain a lateral dopant concentration gradient in the region below the trench. The ion implantation in the trench to form the doped regions below and at the side of the trench can further be performed at an implantation energy so that the partly lateral and partly vertical current path, which is created in the defined region for the extended drain, runs essentially along walls of the trench. The doped regions below and at the side of the trench can be created by ion implantation in plurality of directions, each of which being inclined at the angle to the normal of the substrate surface. The method may further comprise the step of forming a region doped to the second doping type underneath the region below the trench by means of ion implantation through the mask used for doping the regions below and at a side of the trench, the ion implantation to form the region doped to the second doping type being effectuated in a direction, which is inclined at an angle to the normal of the surface of the substrate, to thereby assist in creating a depleted extended drain. The channel region can be formed by ion implantation through a mask, the ion implantation of the channel region being effectuated in a direction, which is inclined at an angle to the normal of the surface of the substrate, to thereby create the channel region at least partly underneath the gate for the DMOS transistor device. The ion implantation for forming the channel region can be performed self-aligned to an edge of the gate of the DMOS transistor device. The first doping type can be n-type and the second doping type can be p-type. The DMOS transistor device can be a power transistor. The monolithically integrated high frequency circuit can be a radio or microwave frequency circuit.

The object can furthermore be achieved by a monolithically integrated DMOS transistor device comprising an extended drain region, a shallow trench isolation region in the extended drain region having substantially vertical sidewalls and a substantially horizontal bottom surface, a gate, source and drain regions doped to a first doping type, and a channel region doped to a second doping type, the channel region interconnecting the source and drain regions via the extended drain region, wherein the extended drain region comprises a region underneath the shallow trench isolation region and a region adjacent the channel region doped to the first doping type to thereby create a partly lateral and partly vertical current path in the extended drain region.

The doped regions underneath and at the side of the shallow trench isolation region may include at least two different segments with different doping concentrations. The doped region underneath the shallow trench isolation region may have a higher dopant concentration than the region at the side of the shallow trench isolation region. The region underneath the shallow trench isolation region may have a lateral dopant concentration gradient. The doped regions underneath and at the side of the shallow trench isolation region can be formed so as to create the partly lateral and partly vertical current path in the extended drain region along the substantially vertical sidewall and the substantially horizontal bottom surface of the shallow trench isolation region. The DMOS transistor device can be implemented in a monolithically integrated high frequency circuit.

According to a first aspect of the present invention, there is provided a method in the fabrication of an integrated high frequency circuit including a DMOS transistor device. The method comprises the steps of providing a substrate, etching a trench in a region defined for an extended drain for the DMOS transistor device, doping a region below the trench and a region at a side of the trench, filling the trench with an insulating material to form a shallow trench isolation region, and forming a gate, a channel region, a source, and a drain for the DMOS transistor device. The step of doping a region below the trench and a region at a side of the trench is performed by means of ion implantation in the etched open recess formed by the etching of the trench, wherein the ion implantation is effectuated through a mask and in a direction, which is inclined at an angle to the normal of the surface of the substrate, to thereby create a partly lateral and partly vertical current path in the extended drain.

The two regions—below and at the side of the trench, respectively—will easily obtain different dopant concentrations due to the angled ion implantation. The relation between the dopant concentrations in the two regions is controlled by means of the angle of the ion implantation—the larger the angle is, the higher dopant concentration is obtained in the region at the side of the trench, and the lower dopant concentration is obtained in the region below the trench. Further, a lateral dopant concentration gradient may be obtained in the region below the trench due to shading effects caused by the upper edges of the trench.

It has thus quite unexpectedly been found a method of creating an extended drain region with at least two differently doped regions in a modern CMOS process based on shallow trench isolation by utilizing a single additional step of angled ion implantation in the etched open trench.

The method of selectively implanting the extended drain region makes it possible to optimize the drain drift region of high voltage and high frequency transistors for use in e.g. radio frequency and microwave circuits.

A minimum of process complexity needs to be added to a conventional BiCMOS or CMOS process in order to include the method of the present invention.

Since the current path will be partially vertical along the wall of the shallow trench, a more compact layout will be achieved, which saves chip area.

The combination of the DMOS power transistor produced according to the present invention with other transistors easily achievable on a single chip and analog, mixed signal and RF BiCMOS devices leads to an attractive variety of circuit design options otherwise not easily available.

Further characteristics of the invention and advantages thereof will be evident from the detailed description of preferred embodiments of the present invention given hereinafter and the accompanying FIGS. 1-6, which are given by way of illustration only, and are thus not limitative of the present invention.

### BRIEF DESCRIPTION OF THE DRAWINGS

FIGS. 1-3 are highly enlarged cross-sectional views of a portion of a semiconductor structure during processing according to a preferred embodiment of the present invention.

FIGS. 4-5 are highly enlarged cross-sectional views during processing according to a further preferred embodiment of the invention.

FIG. 6 is a highly enlarged cross-sectional view during processing according to yet a further preferred embodiment of the invention.

Identical reference numerals are used throughout the Figures to denote identical or similar components, portions, details and the like of the various embodiments.

### DETAILED DESCRIPTION OF PREFERRED EMBODIMENTS

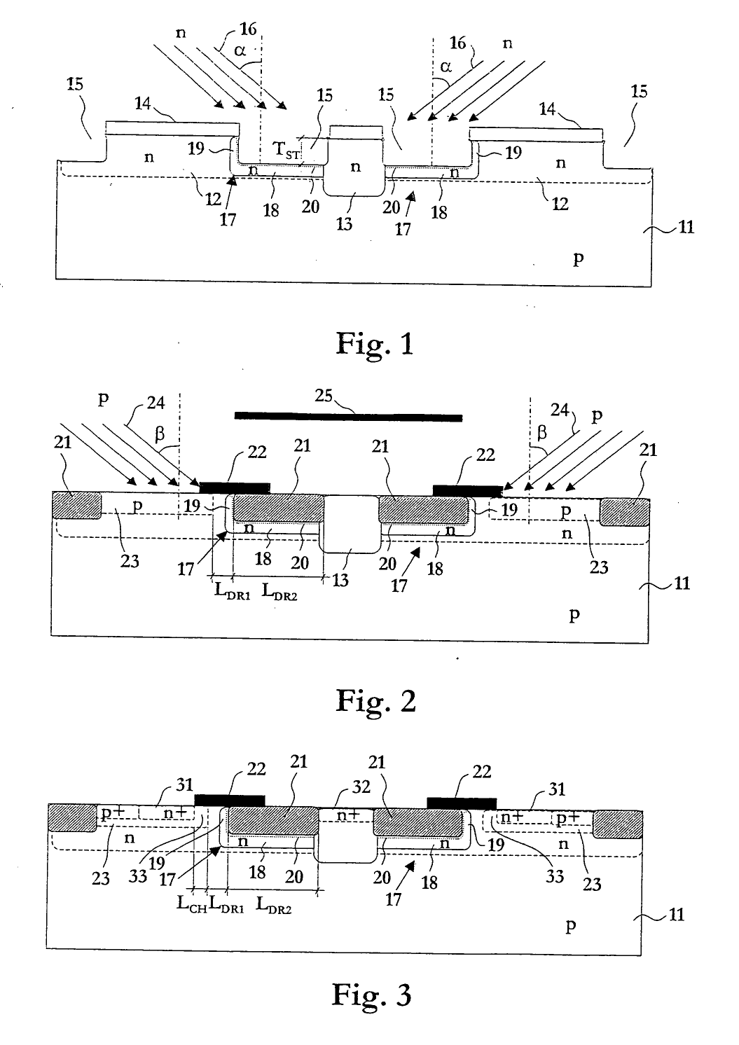

A first preferred embodiment of a method in the fabrication of a monolithically integrated circuit including a DMOS (double diffused MOS) transistor is described below with reference to FIGS. 1-3. The method is implemented in a BiCMOS process. Many of the process steps, e.g. including formation of a gate and ion implantation of wells and source and drain regions, are well known to the person skilled in the art and these steps will therefore not be described at all here, or will only be schematically indicated. The main focus is put on how the extended drain of the DMOS transistor is formed.

A semiconductor structure including a partially processed DMOS transistor is shown in FIG. 1 in a cross section. Reference numeral 11 denotes the p-type doped silicon substrate, 12 denotes an n-type doped well region typically used for bipolar transistors in the BiCMOS process, and 13 denotes an n-type doped well region typically used for MOS transistors in the BiCMOS process. An n⁺-type doped drain for the DMOS transistor will be formed in the well region 13 later in the process, and the well region 13 is therefore in general heavier or much heavier doped than the well region 11.

A shallow trench mask 14 is applied to the thereby obtained structure and patterned to include openings, where shallow trench isolation regions 15 are to be etched. The mask 14 may be a hard mask of e.g. SiO₂ or Si₃N₄ formed in a conventional manner, and optionally a photo resist mask (not illustrated) used for forming the hard mask is left on the structure during the shallow trench etching.

The shallow trenches 15 are etched, wherein the two centrally located trenches 15 in FIG. 1 are formed in a region, which is to become an extended drain for the DMOS transistor. The shallow trenches 15 are typically formed with substantially vertical sidewalls and a substantially horizontal bottom surface. The sidewalls may alternatively have an angle of e.g. up to 10° from the normal of the bottom surface to avoid any mechanical stress. The thickness of the shallow trenches 15 is denoted by TST. If photo resist was left on the structure during etching, this is now removed.

An additional mask (not illustrated) is then advantageously applied on the structure. This mask will preferably substantially cover the whole chip area except the area shallow trenches 15 of the DMOS transistors of the present invention.

In order to obtain the extended drain region, ion implantation 16 with a dopant species of n-type is effectuated in a direction, which is inclined at an angle α to the normal of the surface of the substrate, with the shallow trench mask 14 and the additional mask still present on the structure. Hereby, a drain drift region 17, including a region 18 below the trenches 15 and a region 19 at a side of the trenches 15, is doped to n-type to thereby create a partly lateral and partly vertical current path in the drain drift region 17 for the extended drain. The current path is schematically indicated by the dotted line 20 in FIG. 1.

The angled ion implantation 16 in the etched open trenches 15 is advantageously performed to obtain at least two different segments with different doping concentrations in the doped regions 18, 19 below and at the side of the trenches 15. Particularly, the angled ion implantation 16 is performed to obtain a higher dopant concentration in the region 18 below the trenches 15 than in the region 19 at the side of the trenches 15.

Such non-uniform doping is suitably controlled by the angle α of the angled ion implantation 16 and optionally by rotation of the semiconductor structure in the horizontal plane during the angled ion implantation 16.

Typically, the DMOS transistor of the present invention is oriented parallel with a side of the die, on which it is fabricated. Thus, provided that the orientation of die is known, a symmetrical DMOS transistor, such as the one illustrated in FIGS. 1-3, needs ion implantation to be made at two different rotational orientations in the horizontal plane with 180° between the orientations.

However, a plurality of the DMOS transistor of the present invention may be provided parallel with any side of a rectangular die. In such a case, the ion implantation needs to be made at four different rotational orientations in the horizontal plane with 90° between the orientations.

The angle α of the ion implantation 16 is preferably selected depending on the relation between the desired dopant concentrations of the doped regions 18, 19 below and at the side of the trenches 15. It shall be understood that the smaller the angle α is, the higher dopant concentration is obtained in the region 18 below the trenches 15, and the lower dopant concentration is obtained in the region 19 at the side of the trenches 15.

Further, a lateral dopant concentration gradient in the region 18 below the trenches is obtained at larger values of the angle α due to a shading effect by the semiconductor substrate constituting the sidewalls of the trenches 15.

The implantation energy and dose of the angled ion implantation can be selected to suite the particular application. However, in one preferred version the implantation energy is selected very low, so that the partly lateral and partly vertical current path 20, which is created in the regions 18, 19 below and at the side of the trenches 15, runs essentially along sidewalls and bottom surfaces of the trenches 15.

After the angled ion implantation 16 the mask 14, and the additional mask, are removed.

The trenches 15 are next filled with an insulating material to form shallow trench isolation (STI) regions 21 as can be seen in FIG. 2. A gate 22 for the DMOS transistor is then formed above the doped region 19 at the side of the STI regions 21 and partly above the two centrally located STI regions 21. A p-type doped channel pocket region 23 is formed in the semiconductor structure, preferably self-aligned to edges of the gate 22 of the DMOS transistor. The channel pocket region 23 may advantageously be formed by ion implantation 24 through a mask 25, wherein the ion implantation of the channel pocket region 23 is effectuated in a direction, which is inclined at an angle β to the normal of the surface of the substrate, to thereby create the channel pocket region 23 at least partly underneath the gate 22 of the DMOS transistor. Such angled implantation of a channel pocket region is described in the article by O. Bengtsson, A. Litwin, and J. Olsson referred to in the prior art section, the contents of which being hereby incorporated by reference. The mask 25 is then removed.

The lateral extension of the channel pocket region 23 towards the centrally located STI regions 15 determines the lateral length L_{DR1} of a first part of the drain drift region, whereas the lateral extension of the STI regions 15 sets the lateral length L_{DR2} of a second part of the drain drift region, i.e. the region 19, as being illustrated in FIG. 2. The entire current path in the drain drift region 17, being essentially horizontal-vertical-horizontal, depends thus on the lateral lengths of the first and second parts of the drain drift region L_{DR1} and L_{DR2} as well as on the thickness TST of the shallow trenches 15. By such a structure a more compact layout will be achieved, thereby saving valuable chip area. The DMOS transistor may be referred to as a vertical-lateral DMOS transistor due to the current path in the drain drift region.

Source 31 and drain 32 regions doped to n⁺-type are next formed, preferably by means of ion implantation in any conventional manner. The channel pocket region 23 together with the source region 31 set the lateral dimension of a channel region 33 of the DMOS transistor. The channel region length is denoted by L_{CH} in FIG. 3.

The processing may then continue with silicidation and metallization in a customary manner.

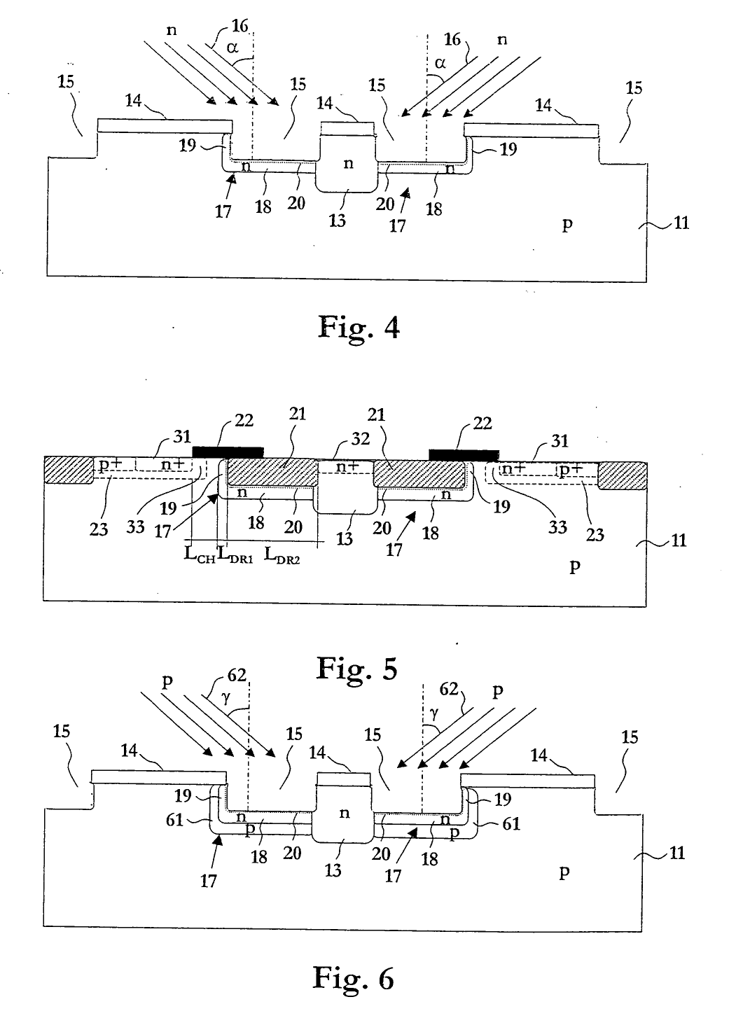

A further preferred embodiment of a fabrication method in accordance with the present invention is illustrated in FIGS. 4-5. Here, no n-type doped well regions typically used for bipolar transistors in a BiCMOS process exist, and therefore this embodiment may be realized in a pure CMOS process. Instead, the angled ion implantation 16 sets the lateral length L_{DR1} of the first part of the drain drift region. Similarly, the channel length is not set by the channel pocket region 23 implantation, but by the angled ion implantation 16 together with the implantation of the source region 31. In other respects this embodiment may be similar to the embodiment described with reference to FIGS. 1-3.

A yet further preferred embodiment of a fabrication method in accordance with the invention is illustrated in FIG. 6. This embodiment is identical with the embodiment described with reference to FIGS. 4-5 except for that it comprises an additional implantation step. A p-type doped region 61 underneath the region 18 is formed by means of ion implantation 62 through the mask 14 used for doping the regions 18, 19 below and at a side of the trenches 15, and the additional mask, as shown in FIG. 4. The ion implantation 62 to form the region 61 is effectuated in a direction, which is inclined at an angle γ to the normal of the surface of the substrate, to thereby assist in creating a depleted extended drain. It shall be appreciated that this additional implantation step shown in FIG. 6 may equally well be applied in connection with the embodiment shown in FIGS. 1-3. The p-type doping is preferably performed to obtain a net doping concentration in the region 61, which is considerably higher than the doping concentration in the substrate 11, but similar to or slightly lower than the net doping concentration in the drain drift region 17.

It shall be appreciated that while the illustrated preferred embodiments of the DMOS transistor is an NMOS device, the present invention is not limited in this respect. The invention is equally applicable to PMOS devices after change of the dopant species used in various fabrication steps.

It shall further be appreciated that while the present invention is primarily intended for radio frequency power silicon DMOS devices, it may as well be useful for smaller devices in silicon-based integrated radio frequency circuits. Thus, the inventive DMOS transistor may be formed with another layout than the one indicated in FIGS. 1-6. Particularly, the transistor has not to be formed symmetrically around a centrally located drain 32.

Still further, the transistor of the present invention may be realized in other materials such as e.g. SiC, GaAs, etc.

1. A method in the fabrication of a monolithically integrated high frequency circuit including a DMOS transistor device, comprising the steps of:
providing a semiconductor substrate,
defining, for said DMOS transistor device, a region for an extended drain in said substrate,
etching a trench in said region for the extended drain,
doping a region below said trench and a region at a side of said trench to a first doping type by means of ion implantation in said trench through a mask, said ion implantation being effectuated in a direction, which is inclined at an angle to the normal of the surface of the substrate, to thereby create a partly lateral and partly vertical current path in said defined region for the extended drain,
filling said trench with an insulating material to form a shallow trench isolation region, and
forming, for said DMOS transistor device, a gate, source and drain regions doped to said first doping type, and a channel region doped to a second doping type, said channel region interconnecting said source and drain regions via said region for the extended drain.

2. The method of claim 1, wherein said ion implantation is performed to obtain at least two different segments with different doping concentrations in said doped regions below and at the side of said trench.

3. The method of claim 1, wherein said ion implantation in said trench to form said doped regions below and at the side of said trench is performed at an angle, which depends on the relation between the desired dopant concentrations of said doped regions below and at the side of said trench.

4. The method of claim 1, wherein said ion implantation in said trench to form said doped regions below and at the side of said trench is performed to obtain a higher dopant concentration in said region below said trench than in said region at the side of said trench.

5. The method of claim 1, wherein said ion implantation in said trench to form said doped regions below and at the side of said trench is performed to obtain a lateral dopant concentration gradient in said region below said trench.

6. The method of claim 1, wherein said ion implantation in said trench to form said doped regions below and at the side of said trench is performed at an implantation energy so that the partly lateral and partly vertical current path, which is created in said defined region for the extended drain, runs essentially along walls of said trench.

7. The method of claim 1, wherein said doped regions below and at the side of said trench are created by ion implantation in plurality of directions, each of which being inclined at said angle to the normal of the substrate surface.

8. The method of claim 1, further comprising the step of forming a region doped to said second doping type underneath said region below said trench by means of ion implantation through said mask used for doping said regions below and at a side of said trench, said ion implantation to form said region doped to said second doping type being effectuated in a direction, which is inclined at an angle to the normal of the surface of the substrate, to thereby assist in creating a depleted extended drain.

9. The method of claim 1, wherein said channel region is formed by ion implantation through a mask, said ion implantation of said channel region being effectuated in a direction, which is inclined at an angle to the normal of the surface of the substrate, to thereby create said channel region at least partly underneath the gate for said DMOS transistor device.

10. The method of claim 9, wherein said ion implantation for forming said channel region is performed self-aligned to an edge of the gate of said DMOS transistor device.

11. The method of claim 1, wherein said first doping type is n-type and said second doping type is p-type.

12. The method of claim 1, wherein said DMOS transistor device is a power transistor.

13. The method of claim 1, wherein said monolithically integrated high frequency circuit is a radio or microwave frequency circuit.

14. A monolithically integrated DMOS transistor device comprising:
an extended drain region,
a shallow trench isolation region in said extended drain region having substantially vertical sidewalls and a substantially horizontal bottom surface,
a gate,
source and drain regions doped to a first doping type,
a channel region doped to a second doping type, said channel region interconnecting said source and drain regions via said extended drain region, wherein said extended drain region comprises a region underneath said shallow trench isolation region and a region adjacent said channel region doped to said first doping type to thereby create a partly lateral and partly vertical current path in said extended drain region.

15. The DMOS transistor device of claim 14, wherein said doped regions underneath and at the side of said shallow trench isolation region includes at least two different segments with different doping concentrations.

16. The DMOS transistor device of claim 15, wherein said doped region underneath said shallow trench isolation region has a higher dopant concentration than said region at the side of said shallow trench isolation region.

17. The DMOS transistor device of claim 15, wherein said region underneath said shallow trench isolation region has a lateral dopant concentration gradient.

18. The DMOS transistor device of claim 14, wherein said doped regions underneath and at the side of said shallow trench isolation region is formed so as to create said partly lateral and partly vertical current path in said extended drain region along said substantially vertical sidewall and said substantially horizontal bottom surface of said shallow trench isolation region.

19. A monolithically integrated high frequency circuit comprising a DMOS transistor device according to claim 14.
